(19) United States
(12) Patent Application Publication
(10) Pub. No.: US 2002/0001877 A1
(43) Pub. Date: Jan. 3, 2002

(54) INTERCONNECT FORMATION IN A SEMICONDUCTOR DEVICE

(76) Inventor: JAE-WOONG KIM, KYUNGKI-DO (KR)

Correspondence Address: SKJERVEN MORRILL MACPHERSON LLP, 25 METRO DRIVE, SUITE 700, SAN JOSE, CA, 95110, US

(21) Appl. No.: 09/388,998

(22) Filed: Sep. 1, 1999

(30) Foreign Application Priority Data
Sep. 2, 1998 (KR) 1998-36093

(51) Int. Cl. H01L 21/44; H01L 21/48; H01L 21/50; H01L 21/4763

(52) U.S. Cl. 438/118

(57) ABSTRACT

A method for forming an interconnect of a semiconductor device includes: forming an interdielectric layer and a polishing stop layer on a semiconductor substrate; forming a depressed region on the substrate where the interconnect is to be formed; forming a conductive layer on the polishing stop layer so that the depressed region is filled with a conductive material; and removing upper portions of the conductive layer by chemical mechanical polishing so as to leave conductive material forming the interconnect in the depressed region. The chemical mechanical polishing selectivity ratio of the conductive layer to the polishing stop layer is 15:1 or more. In order to achieve such polishing selectivity ratio, the polishing stop layer is formed of a nitride layer or a tetraethylortho silicate layer, and the interconnect layer is formed of tungsten. The interdielectric layer is formed of an oxide layer.

### BACKGROUND OF THE INVENTION

1. Field of the Invention

The present invention relates to a method for manufacturing a semiconductor device, and more particularly, to a method for forming an interconnect in a semiconductor device by chemical mechanical polishing.

2. Description of the Related Art

With increasing integration of semiconductor devices, the feature size of the devices decreases. However, the smaller feature size does not equally apply to all dimensions of the device. For example, vertical dimensions, e.g., the thicknesses of interdielectric and interconnect layers, cannot be reduced by the same proportion as horizontal dimensions because reduction of the vertical dimensions can adversely affect characteristics such as break-down voltage, parasitic capacitance, current-handling capability and interconnect resistance of the semiconductor device. Thus, due to the different percentage reductions in the horizontal and the vertical dimensions, the aspect ratios and the relative magnitude of surface irregularities in the devices increase, making manufacturing process more difficult. For example, the surface irregularity varies the distance from the top surface of a semiconductor substrate to a mask depending on the position on the substrate. Accordingly, focusing of a projection lens on the semiconductor substrate becomes so difficult that a desired pattern accuracy cannot be obtained.

The surfaces of semiconductor structures can be planarized to improve the reliability of the manufacturing processes. The planarization can be achieved by borophosphosilicate glass (BPSG) reflow, spin on glass (SOG) etch back, or chemical mechanical polishing (CMP). Chemical mechanical polishing, which uses friction between a slurry and the substrate, can globally planarize the entire surface of the substrate at a low temperature, whereas the reflow or the etch back can partially planarize the surface of the substrate.

Chemical mechanical polishing is used in forming an interconnect as well as the planarization of the interdielectric layer. For example, an insulating layer is etched so as to form an opening such as a contact hole or a via hole, and the opening is filled with a conductive material. Then, the chemical mechanical polishing removes excessive conductive material on the insulating layer, so that the conductive material is only in the opening. A damascene interconnect and a contact plug can be formed by the chemical mechanical polishing. The use of chemical mechanical polishing in forming interconnects prevents step coverage failures caused by the increased aspect ratio of the contact or via hole.

In forming damascene interconnects on a semiconductor substrate by chemical mechanical polishing, since a polishing selectivity ratio of damascene interconnect material, e.g., tungsten layer, to a typical insulating layer, e.g., an oxide layer, is about 7 to 1, the degree of polishing can vary across the substrate depending on the amount of insulating material exposed during polishing. As a result, the damascene interconnects can have different thicknesses, and the resistance of the damascene interconnects becomes non-uniform. Such non-uniformity adversely affects the reliability of a semiconductor device.

### SUMMARY OF THE INVENTION

In accordance with an embodiment of the present invention, a method for forming an interconnect in a semiconductor device includes: forming an interdielectric layer and a polishing stop layer on a semiconductor substrate; forming a depressed region on the substrate where the interconnect is to be formed; forming a conductive layer on the polishing stop layer such that the depressed region is filled with a conductive material; and polishing the conductive layer by chemical mechanical polishing so as to form the interconnect.

According to another aspect of the present invention, a conductive member is formed on the semiconductor substrate. Then, an interdielectric layer and a polishing stop layer are sequentially formed on the entire surface of the semiconductor substrate. Patterning the layers forms a damascene region passing through the polishing stop layer and extending into the interdielectric layer, and/or an opening passing through the polishing stop layer and the interdielectric layer to expose the conductive member. Subsequently, a conductive layer fills the damascene region and the opening. Chemical mechanical polishing of the conductive layer formed on the polishing stop layer leaves a damascene interconnect having a planar surface and a uniform thickness in the damascene region and a contact plug in the opening.

Preferably, the chemical mechanical polishing selectivity ratio of the conductive layer to the polishing stop layer in the chemical mechanical polishing is 15:1 or more. In order to achieve such polishing selectivity ratio, the polishing stop layer is formed of a nitride layer or a tetraethylortho silicate layer, and the interconnection layer is formed of tungsten. The interdielectric layer can be formed of an oxide. Preferably, a slurry used in the chemical mechanical polishing includes alumina.

### BRIEF DESCRIPTION OF THE DRAWINGS

The features and advantages of the present invention will become more apparent by describing in detail particular embodiments thereof with reference to the attached drawings in which:

FIGS. 1 to 6 are sectional views of semiconductor structures illustrating a method for forming an interconnect and/or contact of a semiconductor device according to one embodiment of the present invention.

Use of same reference symbols in different figures indicates similar or identical items.

### DESCRIPTION OF THE PREFERRED EMBODIMENTS

Embodiments of the present invention are described more fully hereinafter in with reference to the drawings. In the following, when a layer is referred to as being “on” another layer or substrate, the layer can be directly on the other layer or substrate, or intervening layers may be present. In the drawings, the thickness of layers and regions are exaggerated for clarity.

Referring to FIG. 1, in manufacturing a semiconductor device in accordance with an embodiment of the present invention, a transistor 25 including a gate electrode 22, a drain region 23, and a source region 24 is formed on a P-type or an N-type semiconductor substrate 10. Then, a first interdielectric layer 30, which is about 10,000 to 15,000 Å thick, is formed on the entire surface of substrate 10. First interdielectric layer 30 can be formed by depositing a flowable insulating material, e.g., an doped oxide such as borophosphosilicate glass (BPSG), phosphosilicate glass (PSG), or borosilicate glass (BSG), or an undoped oxide such as a high temperature oxide (HTO) or a low temperature oxide (LTO). First interdielectric layer 30 initially has an irregular upper surface of due to transistor 25 and other previously formed structures, and thus, first interdielectric layer 30 is planarized by chemical mechanical polishing (CMP).

Then, a polishing stop layer 40, which is about 500 to 1,000 Å thick, is formed on first interdielectric layer 30. Polishing stop layer 40 is formed of a material having a lower chemical-mechanical polishing rate than first interdielectric layer 30 and a lower polishing rate than a conductive layer to be formed on polishing stop layer 40. Thus, a nitride layer such as a silicon oxynitride layer or a silicon nitride layer, or a tetraethylortho silicate layer are suitable for polishing stop layer 40.

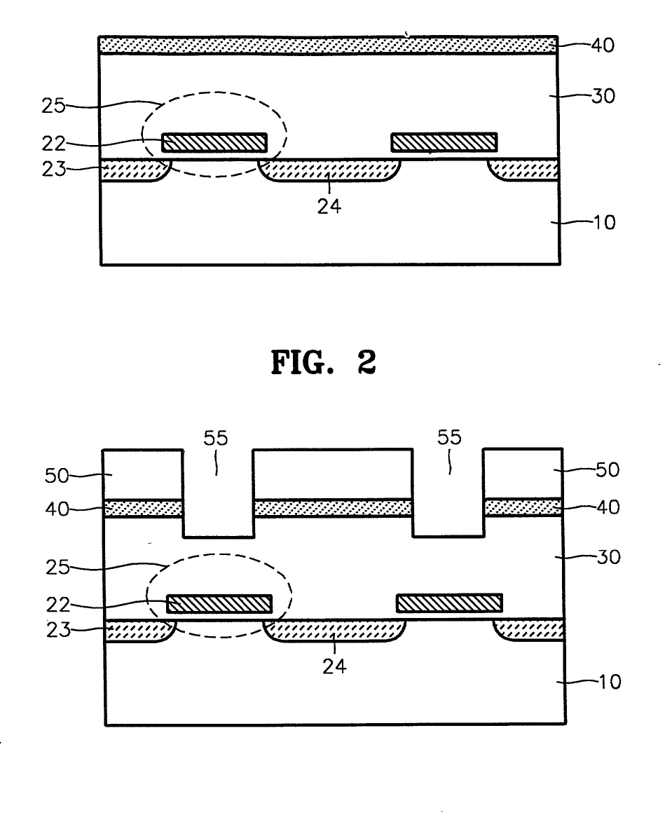

Referring to FIG. 2, a photoresist pattern 50 exposes a region in which a damascene interconnect is to be formed on the structure, and then polishing stop layer 40 and first interdielectric layer 30 are etched using photoresist pattern 50 as an etching mask. The etching forms a depression or damascene region 55 passing through polishing stop layer 40 and extending into first interdielectric layer 30. After the formation of damascene region 55, photoresist pattern 50 is removed. A contact hole (not shown) can be formed in first interdielectric layer 30 before or after the formation of damascene region 55. The contact hole extends from damascene region 55 or the top of polishing stop layer 40 and exposes drain region 23 in substrate 10.

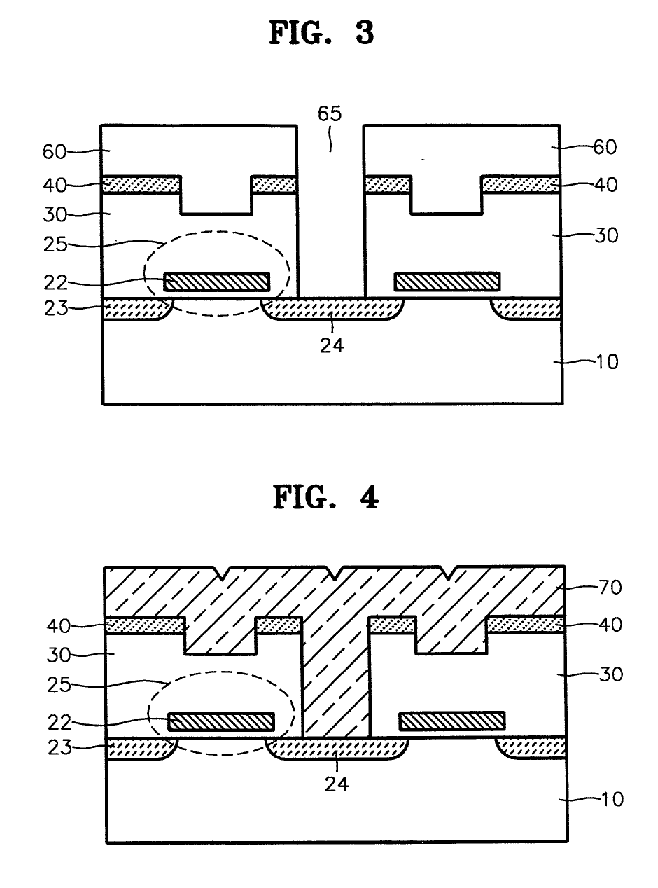

Referring to FIG. 3, after the removal of photoresist pattern 50, a photoresist pattern 60 is formed on damascene region 55 and polishing stop layer 40 and exposes a portion of polishing stop layer 40 where a contact plug is to be formed. Then, polishing stop layer 40 and first interdielectric layer 30 are etched using photoresist pattern 60 as an etching mask to form an opening 65 which exposes source region 24 of transistor 25. Photoresist pattern 60 is then removed.

Referring to FIG. 4, after the removal of photoresist pattern 60, a conductive layer 70, e.g., a tungsten layer, is formed on substrate 10 so that conductive layer 70 fills damascene region 55 and opening 65. Before the formation of conductive layer 70, a refractory metal such as titanium nitride can be deposited on substrate 10 to form a barrier metal layer (not shown).

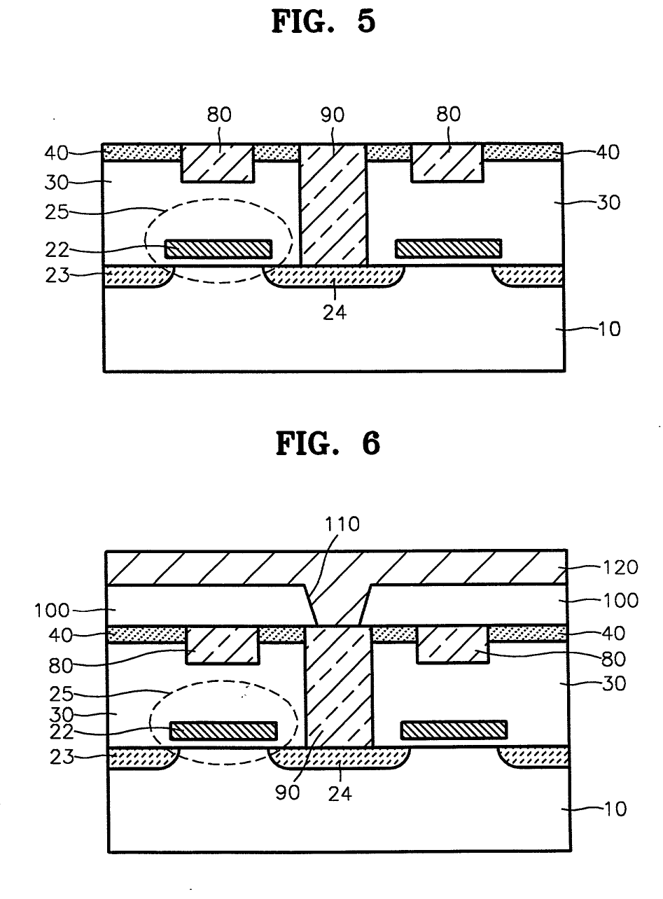

Referring to FIG. 5, after the formation of conductive layer 70, chemical mechanical polishing removes upper portions of conductive layer 70 (FIG. 4) so as to form a damascene interconnect 80 and a contact plug 90. The chemical mechanical polishing preferably has a selectivity ratio of conductive layer 70 to polishing stop layer 40 that is higher than that of conductive layer 70 to first interdielectric layer 30. Thus, the polishing selectivity ratio of conductive layer 70 to polishing stop layer 40 is recommended to be 15:1 or more.

In the chemical mechanical polishing, the slurry of the chemical mechanical polishing oxidizes the irregular surface of conductive layer 70, forming an oxide layer. Then, a polisher mechanically removes the oxide layer from an uppermost portion of the irregular surface of conductive layer 70 by an abrasive action between the polisher and conductive layer 70. A typical slurry for the chemical mechanical polishing includes alumina powder, which is the polisher, and a ferric nitric acid oxidizer. In particular, the compositions the alumina powder and the ferric nitric acid oxidizer determine the polishing selectivity ratio of conductive layer 70 to polishing stop layer 40. When the polishing selectivity ratio of conductive layer 70 to polishing stop layer 40 is high, polishing stop layer 40 is far more slowly removed than conductive layer 70. As a result, polishing stop layer 40 prevents excessive polishing of conductive layer 70 at damascene interconnect 80 and contact plug 90, even when conductive layer 70 at damascene interconnect 80 and contact plug 90 is polished faster than another portion of conductive layer 70 at other damascene interconnects or contact plugs of substrate 10. Therefore, damascene interconnects and contact plugs are uniform across substrate 10.

Referring to FIG. 6, after the formation of damascene interconnect 80 and contact plug 90, a second interdielectric layer 100, e.g., an oxide, is deposited on the entire surface of the resultant structure to form a second interdielectric layer 100, and conventional photolithography and etching processes form a via hole 110 in second interdielectric layer 100 such that via hole 110 exposes a portion of contact plug 90. Then, a conductive material, e.g., aluminum, is deposited on second interdielectric layer 100 and via hole 110 and patterned so as to form an interconnect layer 120 connecting to contact plug 90. Thus, interconnect layer 120 electrically connects to source region 24 through contact plug 90, and can form a storage electrode in a device such as a DRAM cell. According to an aspect of the present invention, a polishing stop layer is on the interdielectric layer where the damascene region is formed. Conductive material fills the damascene region that passes through the polishing stop layer and extends into the interdielectric layer. Subsequent chemical mechanical polishing has a high selectivity ratio of the conductive layer to the polishing stop layer, so that the damascene interconnects of the uniform thickness form.

Although the invention has been described with reference to particular embodiments, the description is only an example of the inventor's application and should not be taken as a limitation. Various adaptations and combinations of features of the embodiments disclosed are within the scope of the invention as defined by the following claims.

What is claimed is:

1. A method for forming a semiconductor device, comprising:
forming an interdielectric layer on the semiconductor substrate;
forming a polishing stop layer on the interdielectric layer;
forming a depressed region in the polishing stop layer;
forming a conductive layer on the polishing stop layer so that a conductive material fills the depressed region; and
polishing a resulting structure to remove upper portions of the conductive layer so that the polishing stop layer is exposed, and the conductive material remains in the depressed region.

2. The method of claim 1, wherein polishing comprises chemical mechanical polishing.

3. The method of claim 2, wherein the chemical mechanical polishing has a selectivity ratio of the conductive layer to the polishing stop layer of 15:1 or more.

4. The method of claim 2, wherein a slurry used in the chemical mechanical polishing comprises alumina powder.

5. The method of claim 2, wherein a slurry used in the chemical mechanical polishing comprises a ferric nitric acid.

6. The method of claim 1, wherein the polishing stop layer comprises a nitride layer.

7. The method of claim 1, wherein the polishing stop layer comprises a tetraethylortho silicate layer.

8. The method of claim 1, wherein the conductive layer is formed of tungsten.

9. The method of claim 1, wherein the interdielectric layer comprises an oxide layer.

10. The method of claim 1, wherein the depressed region extends through the polishing stopping layer and into the interdielectric layer.

11. The method of claim 10, wherein the depressed region is a groove.

12. The method of claim 1, wherein the depressed region extends through the polishing stopping layer and through the interdielectric layer so as to expose a portion of the semiconductor substrate.

13. The method of claim 12, wherein the depressed region is a via hole.
